(19) United States
(12) Patent Application Publication
(10) Pub. No.: US 2011/0284885 A1
(43) Pub. Date: Nov. 24, 2011

(54) LIGHT EMITTIG DEVICE PACKAGE AND IMAGE DISPLAY APPARATUS INCLUDING THE SAME

(75) Inventor: Jun Hee HONG, Seoul (KR)

(73) Assignee: LG INNOTEK CO., LTD., Seoul (KR)

(21) Appl. No.: 13/197,285

(22) Filed: Aug. 3, 2011

(30) Foreign Application Priority Data
Aug. 6, 2010 (KR) 10-2010-0075962

(51) Int. Cl. H01L 33/58; H01L 33/52

(52) U.S. Cl. 257/88; 257/98; 257/E33.059; 257/E33.073

(57) ABSTRACT

Disclosed herein is a light emitting device package including first lead frame and second lead frame mounted on a package body, a light emitting device electrically connected to the first lead frame and second lead frame, to emit light of a first wavelength range, and an encapsulant surrounding the light emitting device, the encapsulant comprising phosphors to be excited by the light of the first wavelength range, thereby emitting light of a second wavelength range, and a resin having a refractive index of 1.1 to 1.3.

### CROSS REFERENCE TO RELATED APPLICATION

This application claims the benefit of Korean Patent Application No. 10-2010-0075962, filed on Aug. 6, 2010, which is hereby incorporated in its entirety by reference as if fully set forth herein.

### FIELD

Embodiments relate to a light emitting device package.

### BACKGROUND

Light emitting devices, such as light emitting diodes (LEDs) and laser diodes (LDs), which use a Group III-V or Group II-VI compound semiconductor material, may render various colors such as red, green, blue, and ultraviolet by virtue of development of thin film growth technologies and device materials. It may also be possible to produce white light at high efficiency using fluorescent materials or through color mixing.

By virtue of development of such technologies, these light emitting elements are increasingly applied not only to display devices, but also to transmission modules of optical communication units, light emitting diode backlights as a replacement for cold cathode fluorescent lamps (CCFLs) constituting backlights of liquid crystal display (LCD) devices, lighting apparatuses using white light emitting diodes as a replacement for fluorescent lamps or incandescent lamps, headlights for vehicles and traffic lights.

LEDs have a structure including a substrate, a P-type electrode, an active layer, and an N-type electrode, which are laminated over the substrate in this order. The N-type electrode is wire-bonded to the substrate, to achieve conduction of current therebetween.

When current is applied to the substrate, holes (+) are discharged from the P-type electrode into the active layer, and electrons (−) are discharged from the N-type electrode into the active layer because the current is supplied to the P and N-type electrodes. Thus, the holes and electrodes are coupled in the active layer, so that a reduction in energy level occurs. Energy discharged in accordance with the energy level reduction is emitted in the form of light.

### SUMMARY

In accordance with an embodiment, an enhancement in light extraction efficiency in a light emitting device is achieved.

Additional advantages, objects, and features of the embodiments will be set forth in part in the description which follows and in part will become apparent to those having ordinary skill in the art upon examination of the following or may be learned from practice of the embodiments. The objectives and other advantages of the embodiments may be realized and attained by the structure particularly pointed out in the written description and claims hereof as well as the appended drawings.

To achieve the objects and other advantages and in accordance with the embodiments, as broadly described herein, a light emitting device package includes first lead frame and second lead frame mounted on a package body, a light emitting device electrically connected to the first lead frame and second lead frame, to emit light of a first wavelength range, and an encapsulant surrounding the light emitting device, the encapsulant including phosphors to be excited by the light of the first wavelength range, thereby emitting light of a second wavelength range, and a resin having a refractive index of 1.1 to 1.3.

The resin may include an epoxy resin, a phenol resin, a thermal conductor, and a flame retardant.

The phosphors may be disposed on the light emitting device in the form of a conformal coating layer.

A refractive index of the conformal coating layer may be lower than a refractive index of the encapsulant.

The light emitting device package may further include a lens disposed on the encapsulant.

The encapsulant may be formed using a dispensing method.

The package body may be flat, and the light emitting device may be mounted on the package body in a flip-chip bonding manner.

The package body may be provided with a cavity, and the light emitting device may be disposed on a bottom of the package body.

The encapsulant may have a convex shape at a central portion of the encapsulant.

In another embodiment, a light emitting device package includes first lead frame and second lead frame mounted on a package body, a light emitting device electrically connected to the first lead frame and second lead frame, to emit light of a first wavelength range, and an encapsulant surrounding the light emitting device, the encapsulant including a first encapsulant to be excited by the light of the first wavelength range, thereby emitting light of a second wavelength range, and a second encapsulant including a resin having a refractive index of 1.1 to 1.3.

The resin may include an epoxy resin, a phenol resin, a thermal conductor, and a flame retardant.

The first encapsulant may be disposed on the light emitting device in the form of a conformal coating layer.

A refractive index of a first encapsulant may be lower than a refractive index of the second encapsulant.

The light emitting device package may further include a lens disposed on the second encapsulant.

The second encapsulant may be formed using a dispensing method.

The package body may be flat, and the light emitting device may be mounted on the package body in a flip-chip bonding manner.

The package body may be provided with a cavity, and the light emitting device may be disposed on a bottom of the package body.

The second encapsulant may have a convex shape at a central portion of the second encapsulant.

In another embodiment, an image display apparatus includes a circuit board, a light emitting device package mounted on the circuit board, the light emitting device package including first lead frame and second lead frame mounted on a package body, a light emitting device electrically connected to the first lead frame and second lead frame, to emit light of a first wavelength range, and an encapsulant surrounding the light emitting device, the encapsulant including phosphors to be excited by the light of the first wavelength range, thereby emitting light of a second wavelength range, and a resin having a refractive index of 1.1 to 1.3, and an optical member to project light emitted from the light emitting device package.

The encapsulant of the light emitting device package includes a first encapsulant including the phosphors, and a second encapsulant including the resin, and a refractive of the first encapsulant may be lower than a refractive index of the second encapsulant.

It is to be understood that both the foregoing general description and the following detailed description of the embodiments are exemplary and explanatory and are intended to provide further explanation of the embodiments as claimed.

### BRIEF DESCRIPTION OF THE DRAWINGS

Arrangements and embodiments may be described in detail with reference to the following drawings in which like reference numerals refer to like elements and wherein:

FIGS. 1A to 1C are sectional views illustrating light emitting device packages according to different exemplary embodiments, respectively;

FIGS. 2A to 2F are views illustrating a method for manufacturing a light emitting device package in accordance with an exemplary embodiment;

FIGS. 3A to 3D are views illustrating a method for manufacturing a light emitting device package in accordance with another exemplary embodiment;

FIGS. 4A to 4C are views illustrating a method for manufacturing a light emitting device package in accordance with another embodiment;

FIG. 5 is a view illustrating a light emitting device package according to another embodiment;

FIG. 6 is a graph depicting the light emitting efficiencies of the light emitting device packages according to the illustrated embodiments;

FIG. 7 is a view illustrating a lighting apparatus, in which light emitting device packages according to any one of the illustrated embodiments are arranged in accordance with an exemplary embodiment; and

FIG. 8 is a view illustrating a display apparatus in which light emitting device packages according to any one of the illustrated embodiments are arranged.

### DETAILED DESCRIPTION

Reference will now be made in detail to preferred embodiments, examples of which are illustrated in the accompanying drawings.

In the following description of the embodiments, it will be understood that, when an element such as a layer (film), region, pattern, or structure is referred to as being “on” or “under” another element, it can be “directly” on or under another element or can be “indirectly” formed such that an intervening element is also present. Also, terms such as “on” or “under” should be understood on the basis of the drawings.

In the drawings, dimensions of layers are exaggerated, omitted or schematically illustrated for clarity and convenience of description. In addition, dimensions of constituent elements do not entirely reflect actual dimensions thereof.

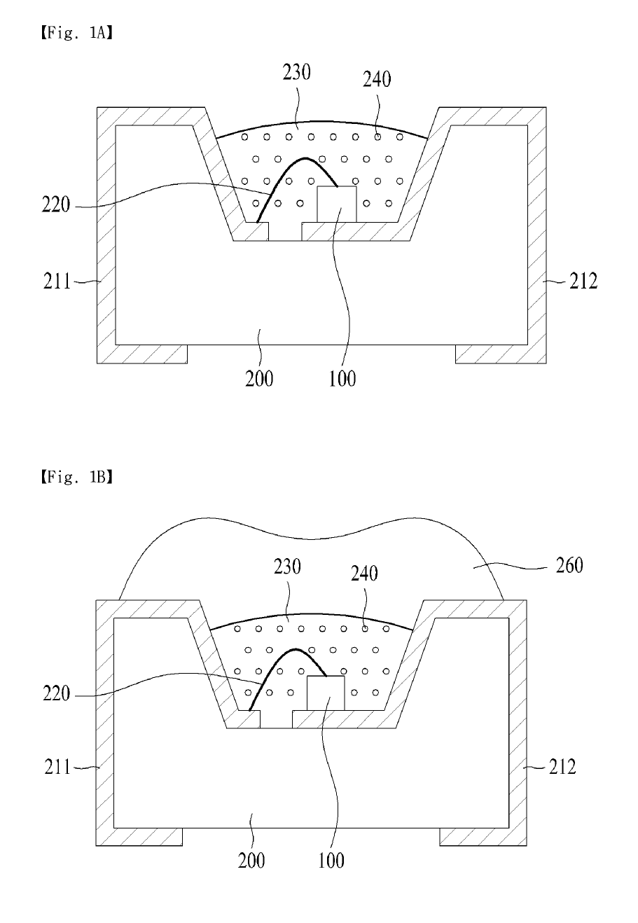

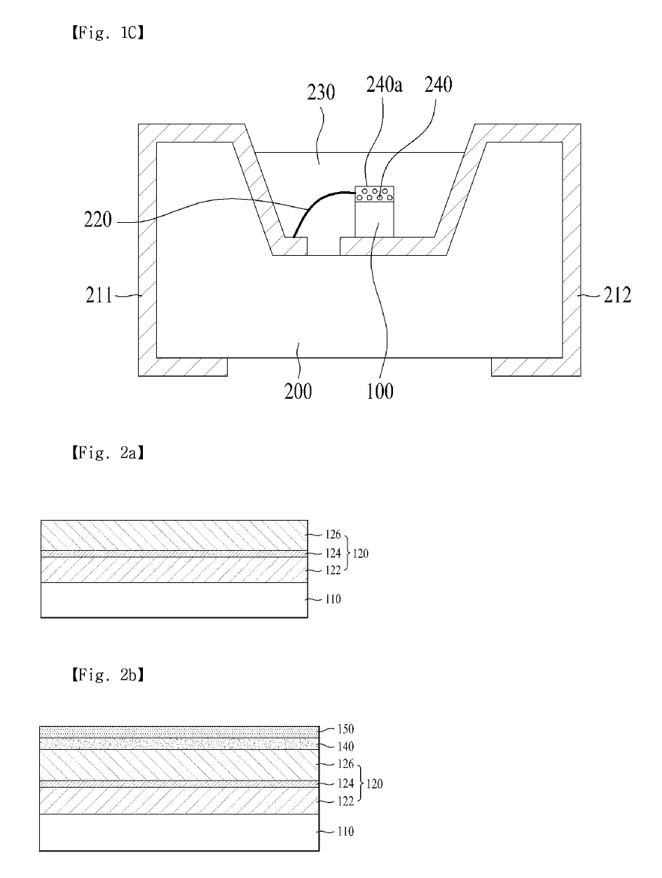

FIG. 1A is a sectional view of a light emitting device package according to an exemplary embodiment.

The light emitting device package according to the illustrated embodiment includes a package body 200, first lead frame and second lead frame 211 and 212 mounted on the package body 200, a light emitting device 100 according to an exemplary embodiment, for example a vertical type or a horizontal type of a light emitting diode including semiconductor, which is mounted on the package body 200, to be electrically connected to the first lead frame and second lead frame 211 and 212, and a phosphor layer surrounding the light emitting device 100. In FIG. 1A, reference numeral “220” is a wire to electrically connect the light emitting device 100 to the first lead frame 211.

The package body 200 may be made of one of a resin material such as polyphthalamide (PPA), silicon (Si), photo-sensitive glass (PSG), sapphire (Al₂O₃), and a printed circuit board (PCB).

The package body 200 may have various top shapes, such as a triangle, a rectangle, a polygon and a circle, according to purposes and designs of the light emitting device package 100. For example, when the light emitting device package 100 has a rectangular top shape, it may be used in an edge-type backlight unit (BLU). If the light emitting device package 100 is applied to a portable flashlight or a home lighting apparatus, the package body 200 may be modified so as to have a size and a shape allowing easy installation within the portable flashlight or the home lighting apparatus.

The package body 200 has a cavity which is upwardly opened and has side surfaces and a bottom. The cavity may have a cup shape or a concave container shape. The side surfaces of the cavity may be perpendicular or tilted with respect to the bottom. The light emitting device 100 is disposed on the bottom of the cavity within the package body 200, as shown in FIG. 1.

The phosphor layer includes a resin 230 and phosphors 240 contained in the resin 230. The phosphor layer is molded in the cavity of the package body 200. In this regard, the phosphor layer may also be referred to as an “encapsulant” in the following description. The resin 230 may be made of an epoxy resin, a phenol resin, a thermal conductor, a flame retardant, etc. The phosphor layer includes one kind of phosphors or at least two kinds of phosphors. The phosphors 240 are excited by light of a first wavelength range, thereby emitting light of a second wavelength range. For example, when the phosphors 240 are excited by blue light emitted from the light emitting device 100, they emit yellow light. In this case, in accordance with the functions of the blue light and yellow light, the light emitting device package may realize white light.

The epoxy resin may have a refractive index of 1.1 to 1.3. The epoxy resin, which has such a low refractive index, may reduce optical loss occurring on the surface of the light emitting device 100, thereby achieving an enhancement in light extraction efficiency.

The phosphor layer may be formed to be higher than an upper surface of the package body 200. Thus, the phosphor layer may have a convex upper surface.

The phosphors 240 may be made of a yttrium-aluminum-garnet (YAG)-based fluorescent material, for example, Y₃Al₅O₁₂. Such YAG-based phosphors may be made of an oxide or a compound easily oxidizable at high temperature, which are produced using Y, Gd, Ce, Sm, Al, and Ga as raw materials.

FIG. 1B is a sectional view illustrating a light emitting device package according to another exemplary embodiment.

The light emitting device package according to this embodiment is similar to that of FIG. 1A, except that a lens 260 is formed over an encapsulant including a resin 230 and phosphors 240. The lens 260 may be formed by applying a silicon gel or epoxy-based resin to the encapsulant using a dispensing method or the like.

FIG. 1C is a sectional view illustrating a light emitting device package according to another exemplary embodiment.

In accordance with this embodiment, a conformal coating layer 240a is disposed on a light emitting device 100. The conformal coating layer 240a includes phosphors 240. A resin 230 surroundes the light emitting device 100 and conformal coating layer 240a.

The conformal coating layer 240a may form a first encapsulant, and the resin 230 may form a second encapsulant. When a refractive index of the conformal coating layer 240a is lower than a refractive index of the resin 230, it may be possible to prevent light emitted from the light emitting device 100 from being fully reflected between the conformal coating layer 240a and the resin 230.

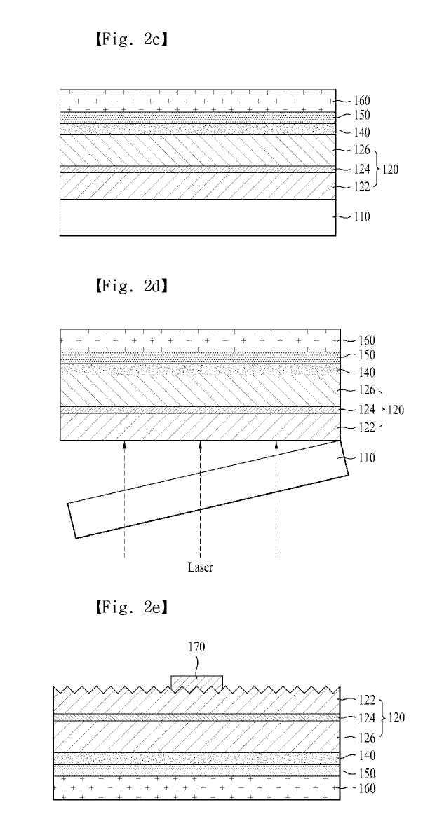

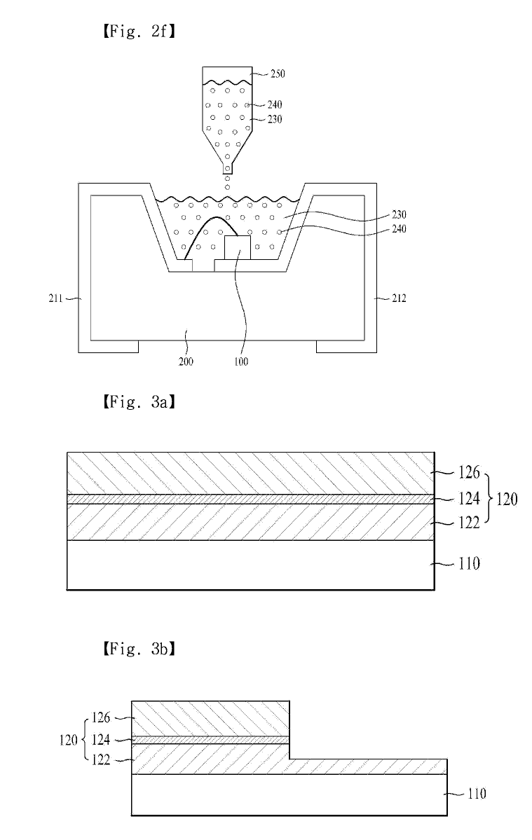

FIGS. 2A to 2F are views illustrating a method for manufacturing a light emitting device package in accordance with an exemplary embodiment.

First, a substrate 110 is prepared as shown in FIG. 2A. The substrate 110 may include a conductive substrate or an insulating substrate. For example, the substrate 110 may be made of at least one of sapphire (Al₂O₃), SiC, Si, GaAs, GaN, ZnO, Si, GaP, InP, Ge, or/and Ga₂O₃. Surface irregularities may be formed over the substrate 110, but the present disclosure is not limited thereto. Impurities on the surface of the substrate 110 may be removed through wet washing.

A light emitting structure 120, which includes a first-conduction-type semiconductor layer 122, an active layer 124, and a second-conduction-type semiconductor layer 126, may be formed over the substrate 110.

In this case, a buffer layer (not shown) may be grown over the light emitting structure 120 and the substrate 110. The buffer layer functions to reduce lattice misalignment and thermal expansion coefficient difference between the materials of the light emitting structure 120 and the substrate 110. The buffer layer may be made of at least one of Group III-V compounds, for example, GaN, InN, AlN, InGaN, AlGaN, InAlGaN, or/and AlInN. An undoped semiconductor layer may be formed over the buffer layer, but the present disclosure is not limited thereto.

The light emitting structure 120 may be grown by a vapor deposition method such as metal organic chemical vapor deposition (MOCVD), molecular beam epitaxy (MBE), or hydride vapor phase epitaxy.

The first-conduction-type semiconductor layer 122 may be made of a Group III-V compound semiconductor doped with a first-conduction-type dopant. When the first-conduction-type semiconductor layer 122 is an N-type semiconductor layer, the first-conduction-type dopant is an N-type dopant. The N-type dopant may include Si, Ge, Sn, Se, or Te, but the present disclosure is not limited thereto.

The first-conduction-type semiconductor layer 122 may be formed into an N-type GaN layer using chemical vapor deposition (CVD), MBE, sputtering, HVPE, or the like. Also, the first-conduction-type semiconductor layer 122 may be formed through injection of tri-methyl gallium gas (TMGa), ammonia gas (NH₃), nitrogen gas (N₂), or silane gas (SiH₄) containing an N-type impurity such as silicon (Si) into a chamber.

The active layer 124 emits light having energy determined by an intrinsic energy band of the material of the active layer 124 as electrons injected into the layer through the first-conduction-type semiconductor layer 122 and holes injected into the active layer 124 through the second-conduction-type semiconductor layer 126 are coupled. That is, the active layer 124 is a light emitting layer.

The active layer 124 may have at least one of a single quantum well structure, a multi quantum well (MQW) structure, a quantum wire structure, or/and a quantum dot structure. For example, the active layer 124 may have an MQW structure through injection of tri-methyl gallium gas (TMGa), ammonia gas (NH₃), nitrogen gas (N₂), and tri-methyl indium gas (TMIn), but the present disclosure is not limited thereto.

The active layer 124 may have a layer pair structure, namely, a well layer/barrier layer structure, made of at least one of InGaN/GaN, InGaN/InGaN, AlGaN/GaN, InAlGaN/GaN, GaAs/AlGaAs (InGaAs), or/and GaP/AlGaP (InGaP), even through the present disclosure is not limited thereto. The well layer may be made of a material having a lower band gap than that of the barrier layer.

A conductive clad layer (not shown) may be formed over and/or beneath the active layer 124. The conductive clad layer may be formed of an AlGaN-based semiconductor. The conductive clad layer may have a higher hand gap than the active layer 124.

The second-conduction-type semiconductor layer 126 may be made of a Group III-V compound semiconductor doped with a second-conduction-type dopant, for example, a semiconductor material having a formula of InₓAl_{y}Ga_{1-x-y}N (0≦x≦1, 0≦y≦1, 0≦x+y≦1). When the second-conduction-type semiconductor layer 126 is a P-type semiconductor layer, the second-conduction-type dopant is a P-type dopant. The P-type dopant may include Mg, Zn, Ca, Sr, Ba, or the like.

The second-conduction-type semiconductor layer 126 may be formed into a P-type GaN layer through injection of tri-methyl gallium gas (TMGa), ammonia gas (NH₃), nitrogen gas (N₂), and biscetyl cyclo pentadienyl magnesium ((EtCp₂Mg){Mg(C₂H₅C₅H₄)₂}) including a P-type impurity such as magnesium (Mg) into a chamber, but the present disclosure is not limited thereto.

In another embodiment, the first-conduction-type semiconductor layer 122 may be implemented by a P-type semiconductor layer, and the second-conduction-type semiconductor layer 126 may be implemented by an N-type semiconductor layer. Over the second-conduction-type semiconductor layer 126, a semiconductor layer having an opposite polarity to the second conduction type may be formed. For example, when the second-conduction-type semiconductor layer 126 is a P-type semiconductor layer, an N-type semiconductor layer (not shown) may be formed over the second-conduction-type semiconductor layer 126. Thus, the light emitting structure 120 may be implemented by one of an N-P junction structure, a P-N junction structure, an N-P-N junction structure, and a P-N-P junction structure.

As shown in FIG. 2B, an ohmic layer 140 and a reflective layer 150 are then formed over the second-conduction-type semiconductor layer 126.

The ohmic layer 140 may be made of at least one of indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IZO nitride (IZON), Al—GaZnO (AGZO), In—GaZnO (IGZO), ZnO, IrOₓ, RuOₓ, NiO, RuOₓ/ITO, Ni/IrOₓ/Au, Ni/IrOₓ/Au/ITO, Ag, Ni, Cr, Ti, Al, Rh, Pd, Ir, Ru, Mg, Zn, Pt, Au, or/and Hf, but the present disclosure is not limited thereto. The ohmic layer 140 may be formed using sputtering or electron beam deposition.

The reflective layer 150 may be formed of a metal layer including aluminum (Al), silver (Ag), platinum (Pt), rhodium (Rh), or an alloy containing Al, Ag, Pt, or Rh. Al, Ag, or the like may effectively reflect light emitted from the active layer 124, thereby achieving a great enhancement in the light extraction efficiency of the light emitting device.

As shown in FIG. 2C, a conductive support substrate 160 may then be formed over the reflective layer 150. The conductive support substrate 160 may be made of a material selected from the group consisting of molybdenum (Mo), silicon (Si), tungsten (W), copper (Cu), and aluminum (Al), or an alloy thereof. The conductive support substrate 160 may selectively include gold (Au), copper alloy, nickel (Ni), copper-tungsten alloy (Cu—W), carrier wafer (ex.: GaN, Si, Ge, GaAs, ZnO, SiGe, SiC, SiGe, Ga₂O₃, etc.), etc. The conductive support substrate 160 may be formed using an electro-chemical metal deposition method or a bonding method using eutectic metals.

Thereafter, the substrate 110 is removed as shown in FIG. 2D. The removal of the substrate 110 may be achieved by a laser lift-off (LLO) method using an excimer laser or a dry or wet etching method.

Hereinafter, removal of the substrate 110 through the LLO method will be described in brief. When an excimer laser beam of a predetermined wavelength range is irradiated toward the substrate 110 in a focused state, thermal energy is concentrated on an interface between the substrate 110 and the light emitting structure 120, so that the interface is split into gallium and nitrogen molecules. As a result, instantaneous separation of the substrate 110 occurs in a region upon which the laser beam is incident.

Irregularities are then formed over the surface of the first-conduction-type semiconductor layer 122, as shown in FIG. 2E. The surface irregularities may be formed using a photo-enhanced-electrochemical (PEC) process or an etching process using a mask. In this case, irregularities having fine patterns may be formed by adjusting the amount of a liquid etchant (for example, KOH), the intensity and exposure time of ultraviolet (UV) rays, the etch rate difference between the gallium-polar material and the nitrogen-polar material, and etch rate difference caused by GaN crystallinity.

The etching process, which uses a mask, is carried out by coating photoresist over the first-conduction-type semiconductor layer 122, and performing an exposure process using a mask. After the exposure process, a development process is performed to form an etching pattern. In accordance with these processes, an etching pattern is formed on the first-conduction-type semiconductor layer 122. An etching process is then performed to form surface irregularities over the first-conduction-type semiconductor layer 122. Preferably, the surface irregularities have increased numbers of ridges and valleys, in order to increase the surface area of the first-conduction-type semiconductor layer 122.

A first electrode 170 is then formed on the first-conduction-type semiconductor layer 122. The first electrode 170 is made of a metal selected from chromium (Cr), nickel (Ni), gold (Au), aluminum (Al), titanium (Ti), and platinum (Pt), or an alloy thereof.

Although not shown, a passivation layer may be deposited on a side surface of the light emitting structure 120. The passivation layer may include a silicon oxide (SiO₂) layer, an oxidized nitride layer, or an aluminum oxide layer, which has non-conductive insulation properties.

Referring to FIG. 2F, a process for injecting a phosphor layer into a light emitting device package, which includes the above-described light emitting device 100, is illustrated.

The phosphor layer includes a resin 230 made of an epoxy-based resin and phosphors 240 contained in the resin 230. Referring to the above description, the concrete compositions of the resin 230 and phosphors 240 can be seen. For example, YAG-based phosphors may be made of an oxide or a compound easily oxidizable at high temperature, which are produced using Y, Gd, Ce, Sm, Al, and Ga as raw materials. In detail, the raw materials are mixed to prepare a raw material mixture. An appropriate amount of fluoride such as ammonium fluoride (NH₄F) is mixed, as a flux, with the raw material mixture. The resultant mixture is loaded into a crucible, and is then cured at a temperature of 1,350 to 1,450° C. for 2 to 5 hours. The cured product is subjected to cleaning, separation, drying, etc., to produce phosphors.

As shown in FIG. 2F, the phosphor layer, which includes the resin 230 and phosphors 240, is molded in a cavity formed at the package body 200, using a dispenser 250, such that the phosphor layer surroundes the light emitting device 100. Thus, a encapsulant, which includes the resin 230 and phosphors 240, is formed. In this case, a lens (not shown) may be formed on the package body 200 and the phosphor layer, namely, the encapsulant. The lens may be formed by applying a silicon gel or epoxy-based resin to the package body 200 and the phosphor layer using a dispensing method or the like. As described above, the phosphor layer may be filled to be higher than an upper surface of the package body 200.

At least one of light emitting devices, which have been described above or will be described hereinafter, may be mounted on the light emitting device package, but the present disclosure is not limited thereto.

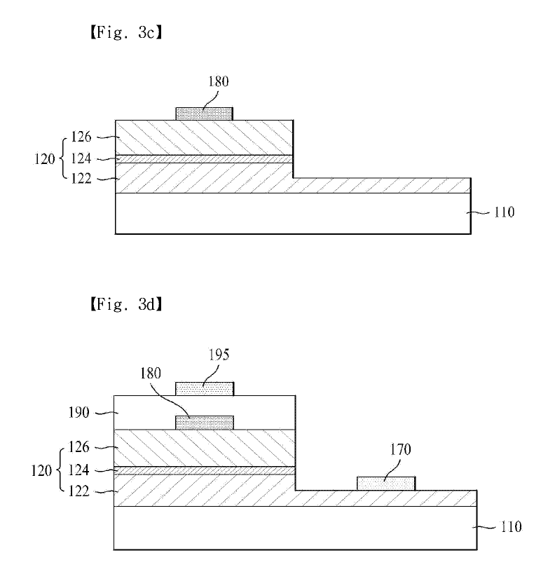

FIGS. 3A to 3D are views illustrating a method for manufacturing a light emitting device package in accordance with another exemplary embodiment.

First, as shown in FIG. 3A, a light emitting structure 120, which includes a first-conduction-type semiconductor layer 122, an active layer 124, and a second-conduction-type semiconductor layer 126, may be formed over a substrate 110. This process is identical to the process shown in FIG. 2A and, as such, no description thereof will be given.

Thereafter, as shown in FIG. 3B, the resultant structure is mesa-etched from the second-conduction-type semiconductor layer 126 to a portion of the first-conduction-type semiconductor layer 122, using a reactive ion etching (RIE) method. Since it is impossible to form an electrode beneath the substrate 110 when an insulating substrate such as a sapphire substrate is used for the substrate 110, the light emitting structure 120 is mesa-etched from the second-conduction-type semiconductor layer 126 to a portion of the first-conduction-type semiconductor layer 122, to secure a space for formation of the electrode.

As shown in FIG. 3C, a current blocking layer 180 may be formed on the second-conduction-type semiconductor layer 126. The current blocking layer 180 may be made of an insulating material or a metal. The current blocking layer 180 may be patterned using a mask (not shown). The current blocking layer 180 may be formed to correspond to a second electrode 160, which will be subsequently formed, as shown in FIG. 3D. Since current in the light emitting device may be concentrated on a central portion of the nitride semiconductor, the current blocking layer 140 may be formed using a metal or insulating material in order to reduce the concentration of current.

Thereafter, a transparent conductive layer 190 may be formed over the second-conduction-type semiconductor layer 126 and current blocking layer 180, as shown in FIG. 3D. The transparent blocking layer 190 may be formed by laminating a single metal, a metal alloy, or a metal oxide in the form of a multilayer structure. For example, the transparent conductive layer 190 may be made of at least one of indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IZO nitride (IZON), Al—GaZnO (AGZO), In—GaZnO (IGZO), ZnO, IrOₓ, RuOₓ, NiO, RuOₓ/ITO, Ni/IrOₓ/Au, Ni/IrOₓ/Au/ITO, Ag, Ni, Cr, Ti, Al, Rh, Pd, Ir, Ru, Mg, Zn, Pt, Au, or/and Hf, but the present disclosure is not limited thereto.

The second electrode 195 may be formed on the transparent conductive layer 190. The second electrode 195 may be made of a metal selected from the group consisting of chromium (Cr), nickel (Ni), gold (Au), aluminum (Al), titanium (Ti), and platinum (Pt), or an alloy thereof. A first electrode 170 may be formed on the exposed portion of the first-conduction-type semiconductor layer 122, using a metal selected from the group consisting of Cr, Ni, Au, Al, Ti, and Pt, or an alloy thereof.

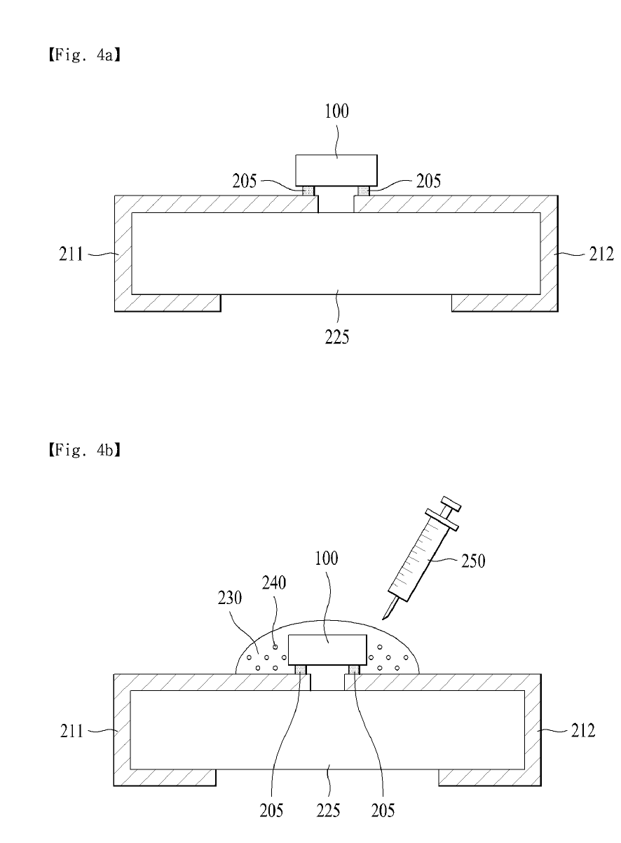

FIGS. 4A to 4C are views illustrating a method for manufacturing a light emitting device package in accordance with another embodiment.

In this embodiment, a light emitting device 100 is mounted on a package body 225 having a flat shape in a flip-chip bonding manner, differently than in the previous embodiments. In this case, the light emitting device 100 may be of a vertical type or a horizontal type. A first lead frame 211 and a second lead frame 212 are mounted on the flat package body 225. The light emitting device 100 may be fixed to the first lead frame and the second lead frame 211 and 212 by solder layers 205. The solder layers 205 may be made of a conductive material. The compositions of the package body 225 and lead frames 211 and 212 may be identical to the embodiment of FIG. 1 or other embodiments.

As shown in FIG. 4B, a phosphor layer is coated over the package body 225, on which the light emitting device 100 is mounted, to surround the light emitting device 100. The phosphor layer may include a resin 230 made of a silicon (Si) or epoxy-based resin, and phosphors 240 contained in the resin 230. Referring to the above description, the concrete configuration of the phosphor layer can be seen.

The coating of the phosphor layer is achieved using a dispenser 250. In order to prevent the material of the phosphor layer from flowing laterally, a ring (not shown) may be temporarily provided on the package body 225.

When the phosphor layer, which includes the resin 230 and phosphors 240, is cured, a light emitting device package as shown in FIG. 4C is completed. In this case, a lens 270 may be formed on the phosphor layer. The lens 270 may be formed by applying a silicon gel or epoxy-based resin to the phosphor layer using a dispensing method or the like.

In the light emitting device package according to this embodiment, the light emitting device 100 is mounted on the flat package body 225 in a flip-chip bonding manner, and is surrounded by the phosphor layer, namely, the resin 230 and phosphors 240, and the lens 270. Enhancement of light extraction efficiency achieved in accordance with the refractive index relation between the light emitting device 100 and the phosphor layer is identical to those of the previous embodiments and, as such, no description thereof will be given.

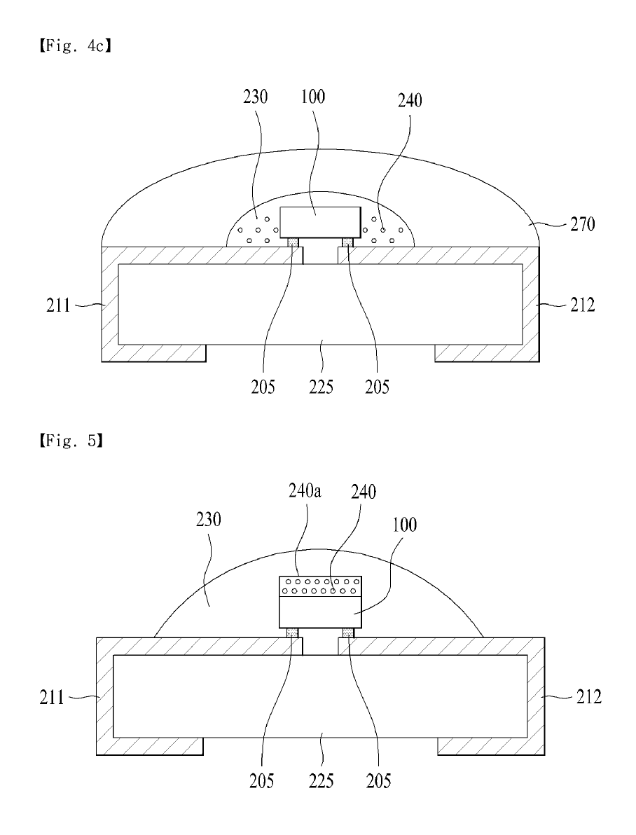

FIG. 5 is a view illustrating a light emitting device package according to another embodiment.

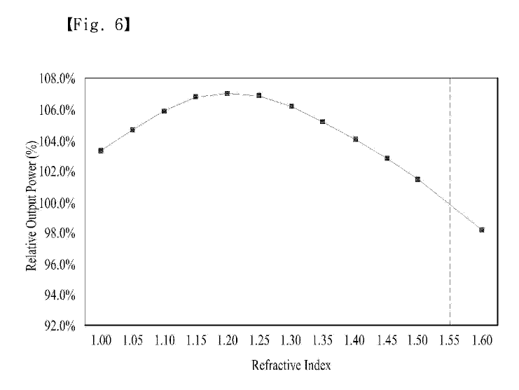

This embodiment is similar to the embodiment of FIG. 4C, except that phosphors are contained in a conformal coating layer 240a, which is formed, as a first encapsulant, on a light emitting device 100. A resin 230 as a second encapsulant surroundes the light emitting device 100 and conformal coating layer 240a. A lens (not shown) may be formed around the resin 230. FIG. 6 is a graph depicting the light emitting efficiencies of the light emitting device packages according to the illustrated embodiments. The optical output power of a bare chip, which is not formed with a phosphor layer, is set to 100% as a reference optical output power. In the case of a light emitting device package, in which a phosphor layer is formed using an epoxy resin having a refractive index of 1.2, a relative optical output power of 107% is generated. On the other hand, In the case of a light emitting device package, in which a phosphor layer is formed using an epoxy resin having a refractive index of 1.1 to 1.3, a relative optical output power of 106% is generated. It can be seen that such optical outputs are enhanced over a relative optical output power of 103.3% generated in the case in which a resin having a general refractive index of 1.53 is used.

The light emitting device package according to any one of the above-described embodiments may be arrayed in plural on a substrate. Optical members, namely, a light guide plate, a prism sheet, diffusion sheet, etc., may be arranged on optical paths of the light emitting device packages. The light guide plate, prism sheet, and diffusion sheet may function as a light unit. In accordance with another embodiment, an image display apparatus, an indication apparatus or a lighting system may be implemented using the semiconductor light emitting devices or light emitting device packages described in conjunction with the above-described embodiments. The lighting system may include, for example, a lamp or a street lamp.

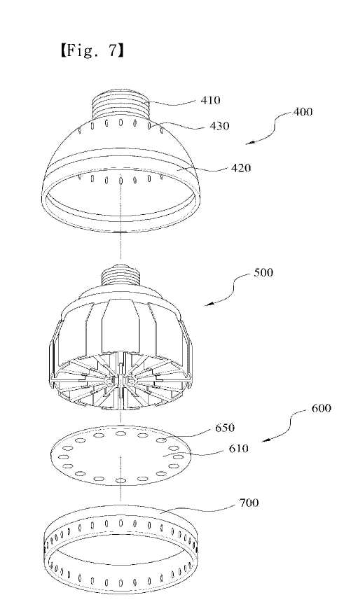

FIG. 7 is a view illustrating a lighting apparatus, in which light emitting device packages according to any one of the above-described embodiments are arranged in accordance with an exemplary embodiment.

The lighting apparatus includes a light source 600 for projecting light, a housing 400 in which the light source 600 is mounted, a heat dissipation unit 500 for dissipating heat generated from the light source 600, and a holder 700 for coupling the light source 600 and heat dissipation unit 500 to the housing 400.

The housing 400 includes a socket connection part 410 connected to an electric socket (not shown), and a body part 420 connected to the socket connection part 410. The light source 600 is received in the body part 420. A plurality of air holes 430 may be formed through the body part 420.

Although a plurality of air holes 430 are formed through the body part 420 of the housing 400 in the illustrated case, a single air hole 430 may be formed through the body part 420. Although the plural air holes 430 are circumferentially arranged, various arrangements thereof may be possible.

The light source 600 includes a circuit board 610 and a plurality of light emitting device packages 650 mounted on the circuit board 610. Here, the circuit board 610 may be shaped to be fitted in an opening formed at the housing 400. Also, the circuit board 610 may be made of a material having high thermal conductivity so as to transfer heat to the heat dissipation unit 500, as will be described later.

The holder 700 is disposed under the light source 600. The holder 700 includes a frame and air holes. Although not shown, an optical member may be disposed under the light source 600 so as to diffuse, scatter or converge light projected from the light emitting device packages 650 of the light source 600.

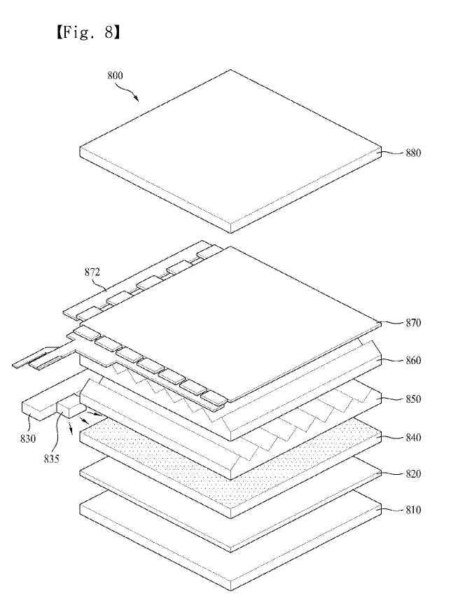

FIG. 8 is a view illustrating a display apparatus in which light emitting device packages according to any one of the above-described embodiments are arranged.

As shown in FIG. 8, the display apparatus according to the illustrated embodiment, which is designated by reference numeral 800, includes a light source module, a reflective plate 820 provided on a bottom cover 810, a light guide plate 840 disposed in front of the reflective plate 820 to guide light emitted from the light source module 830 to a front side of the display apparatus 800, first and second prism sheets 850 and 860 disposed in front of the light guide plate 840, a panel 870 disposed in front of the second prism sheet 860, and a color filter 880 disposed in front of the panel 870.

The light source module includes a circuit board 830 and light emitting device packages 835 mounted on the circuit board 830. Here, a printed circuit board (PCB) may be used as the circuit board 830. The light emitting device packages 835 may have the above-described configuration.

The bottom cover 810 serves to receive the constituent elements of the display apparatus 800. The reflective plate 820 may be provided as a separate element, as shown in FIG. 8, or may be provided as a material having high reflectivity is coated over a rear surface of the light guide plate 840 or a front surface of the bottom cover 810.

Here, the reflective plate 820 may be made of a material having high reflectivity and capable of being formed into an ultra thin structure. Polyethylene terephthalate (PET) may be used for the reflective plate 820.

The light guide plate 840 serves to scatter light emitted from the light source module so as to uniformly distribute the light throughout all regions of a liquid crystal display apparatus. Therefore, the light guide plate 840 may be made of a material having high refractivity and transmissivity. The material of the light guide plate 840 may include polymethylmethacrylate (PMMA), polycarbonate (PC) or polyethylene (PE). The light guide plate may be dispensed with. In this case, an air guide system, which transfers light in a space over the reflective sheet 820, may be implemented.

The first prism sheet 850 may be formed by coating a polymer exhibiting light transmittance and elasticity over one surface of a base film. The first prism sheet 850 may have a prism layer having a plurality of three-dimensional structures in the form of a repeated pattern. Here, the pattern may be a stripe type in which ridges and valleys are repeated.

The second prism sheet 860 may have a similar structure to the first prism sheet 850. The second prism sheet 860 may be configured such that the orientation direction of ridges and valleys formed on one surface of the base film of the second prism sheet 860 is perpendicular to the orientation direction of the ridges and valleys formed on one surface of the base film of the first prism sheet 850. Such a configuration serves to uniformly distribute light transmitted from the light module and the reflective sheet 820 toward the entire surface of the panel 870.

In the illustrated embodiment, an optical sheet may be constituted by the first prism sheet 850 and second prism sheet 860. However, the optical sheet may include other combinations, for example, a microlens array, a combination of a diffusion sheet and a microlens array, and a combination of a prism sheet and a microlens array.

A liquid crystal display panel may be used as the panel 870. Further, instead of the liquid crystal display panel 870, other kinds of display devices requiring light sources may be provided.

The display panel 870 is configured such that a liquid crystal layer is located between transparent substrates, for instance glass bodies, and polarizing plates are disposed on both glass bodies so as to utilize polarizing properties of light. Here, the liquid crystal layer has properties between a liquid and a solid. That is, in the liquid crystal layer, liquid crystals which are organic molecules having fluidity like the liquid are regularly oriented, and the liquid crystal layer displays an image using change of such molecular orientation due to an external electric field.

The liquid crystal display panel used in the display apparatus is of an active matrix type, and uses transistors as switches to adjust voltage applied to each pixel.

The color filter 880 is provided on the front surface of the panel 870, and transmits only an R, G or B light component of light projected from the panel 870 per pixel, thereby displaying an image.

As apparent from the above description, the light emitting device package according to any one of the above-described embodiments achieves an enhancement in light extraction efficiency.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device package comprising:
first lead frame and second lead frame mounted on a package body;
a semiconductor light emitting device electrically connected to the first lead frame and the second lead frame, to emit light of a first wavelength range,; and
an encapsulant surrounding the semiconductor light emitting device, the encapsulant comprising phosphors to be excited by the light of the first wavelength range, thereby emitting light of a second wavelength range, and a resin having a refractive index of 1.1 to 1.3.

2. The light emitting device package according to claim 1, wherein the resin comprises at least one of an epoxy resin, a phenol resin, a thermal conductor, or/and a flame retardant.

3. The light emitting device package according to claim 1, wherein the phosphors are disposed on the semiconductor light emitting device in the form of a conformal coating layer.

4. The light emitting device package according to claim 3, wherein a refractive index of the conformal coating layer is lower than a refractive index of the resine.

5. The light emitting device package according to claim 1, further comprising:
a lens disposed on the encapsulant.

6. The light emitting device package according to claim 1, wherein the encapsulant is formed using a dispensing method.

7. The light emitting device package according to claim 1, wherein the package body is flat, and the semiconductor light emitting device is mounted on the package body in a flip-chip bonding method.

8. The light emitting device package according to claim 1, wherein the package body has a cavity, and the semiconductor light emitting device is disposed on a bottom of the cavity.

9. The light emitting device package according to claim 1, wherein the encapsulant has a convex shape at a central portion of the encapsulant.

10. A light emitting device package comprising:
first lead frame and second lead frame mounted on a package body;
a light emitting device electrically connected to the first lead frame and second lead frame, to emit light of a first wavelength range, the light emitting device including light emitting diode; and
an encapsulant surrounding the light emitting device, the encapsulant comprising a first encapsulant to be excited by the light of the first wavelength range, thereby emitting light of a second wavelength range, and a second encapsulant comprising a resin having a refractive index of 1.1 to 1.3.

11. The light emitting device package according to claim 10, wherein the second encapsulant comprises at least one of an epoxy resin, a phenol resin, a thermal conductor, or/and a flame retardant.

12. The light emitting device package according to claim 10, wherein the first encapsulant is disposed on the light emitting device in the form of a conformal coating layer.

13. The light emitting device package according to claim 12, wherein a refractive index of the first encapsulant is lower than a refractive index of the second encapsulant.

14. The light emitting device package according to claim 10, further comprising:
a lens disposed on the second encapsulant.

15. The light emitting device package according to claim 10, wherein the second encapsulant is formed using a dispensing method.

16. The light emitting device package according to claim 10, wherein the package body is flat, and the light emitting device is mounted on the package body in a flip-chip bonding method.

17. The light emitting device package according to claim 10, wherein the package body has a cavity, and the light emitting device is disposed on a bottom of the cavity.

18. The light emitting device package according to claim 10, wherein the second encapsulant has a convex shape at a central portion of the second encapsulant.

19. An image display apparatus comprising:
a light source module includes a circuit board and a light emitting device package, light emitting device package mounted on the circuit board, the light emitting device package comprising first lead frame and second lead frame mounted on a package body, a light emitting device electrically connected to the first lead frame and second lead frame, the light emitting device including light emitting diode, to emit light of a first wavelength range, and an encapsulant surrounding the light emitting device, the encapsulant comprising phosphors to be excited by the light of the first wavelength range, thereby emitting light of a second wavelength range, and a resin having a refractive index of 1.1 to 1.3;
an optical member to project light emitted from the light emitting device package; and
a panel includes a first transparent substrate, a second transparent substrate, a plurality of liquid crystal disposed between the first transparent substrate and a second transparent substrate, polarizing plates is disposed on the first transparent substrate and a second transparent substrate respectively, the panel transmits the light projected from the optical member.

20. The image display apparatus according to claim 19, wherein the encapsulant of the light emitting device package comprises a first encapsulant comprising the phosphors, and a second encapsulant comprising the resin, and a refractive of the first encapsulant is lower than a refractive index of the second encapsulant.
